(19) United States
(12) Patent Application Publication
(10) Pub. No.: US 2019/0233940 A1
(43) Pub. Date: Aug. 1, 2019

(54) TREATMENT METHODS FOR SILICON NITRIDE THIN FILMS

(71) Applicant: Applied Materials, Inc., Santa Clara, CA (US)

(72) Inventors: Jinrui GUO, Santa Clara, CA (US); Jingmei LIANG, San Jose, CA (US); Praket P. JHA, San Jose, CA (US); Tejasvi ASHOK, San Jose, CA (US); Tza-Jing GUNG, San Jose, CA (US)

(21) Appl. No.: 16/256,670

(22) Filed: Jan. 24, 2019

Related U.S. Application Data
(60) Provisional application No. 62/622,357, filed on Jan. 26, 2018.

(51) Int. Cl. C23C 16/452; C23C 16/34; H01L 21/02

(52) U.S. Cl. CPC C23C 16/452; C23C 16/345; H01L 21/02222; H01L 21/02271; H01L 21/02337; H01L 21/0217

(57) ABSTRACT

Embodiments herein provide for radical based treatment of silicon nitride layers deposited using a flowable chemical vapor deposition (FCVD) process. Radical based treatment of the FCVD deposited silicon nitride layers desirably increases the number of stable Si—N bonds therein, removes undesirably hydrogen impurities therefrom, and desirably provides for further crosslinking, densification, and nitridation (nitrogen incorporation) in the resulting silicon nitride layer. In one embodiment, a method of forming a silicon nitride layer includes positioning a substrate on a substrate support disposed in the processing volume of a processing chamber and treating a silicon nitride layer deposited on the substrate. Treating the silicon nitride layer includes flowing one or more radical species of a first gas comprising NH₃, N₂, H₂, Ar, He, or combinations thereof and exposing a silicon nitride layer to the radical species.

### CROSS-REFERENCE TO RELATED APPLICATIONS

This application claims priority to U.S. Provision Application Ser. No. 62/622,357, filed on Jan. 26, 2018, which is herein incorporated by reference in its entirety.

### BACKGROUND

### Field

Embodiments of the present disclosure generally relate to the field of semiconductor device manufacturing processes, and more particularly, to methods for radical based treatment of a silicon nitride layer which has been deposited onto a substrate surface in an electronic device fabrication process.

### Description of the Related Art

Silicon nitride is commonly used as a dielectric material in electronic device fabrication processes, such as insulator layers between metal levels, barrier layers to prevent oxidation or other diffusion, hard masks, passivation layers, spacer materials such as used in transistors, anti-reflective coating materials, layers in non-volatile memories, and as a gap fill material in trenches between device features to reduce cross-talk therebetween. Often, silicon nitride layers are further treated, after the deposition thereof, to achieve a desired film stoichiometry, etch selectivity, and other desirable film properties. Conventional treatment methods include exposing the silicon nitride layer to a high density plasma (HDP). However, conventional treatment methods create a risk of damaging underlying features and materials on the substrate due to ion bombardment thereof or are otherwise inadequate for treating silicon nitride material disposed in high aspect ratio openings.

Accordingly, what is needed in the art are improved methods of treating a deposited silicon nitride layer to achieve a desired silicon nitride stoichiometry and other desired material properties thereof.

### SUMMARY

Embodiments described herein generally provide for radical based treatment of silicon nitride layers deposited using a flowable chemical vapor deposition (FCVD) process. In some embodiments, the methods further include depositing the silicon nitride layers prior to the treatment thereof.

In one embodiment, a method of processing a substrate includes positioning the substrate on a substrate support disposed in the processing volume of a processing chamber and treating a silicon nitride layer which has been deposited on the substrate. Treating the silicon nitride layer includes flowing one or more radical species of a first gas comprising NH₃, N₂, H₂, He, Ar, or combinations thereof and exposing a silicon nitride layer to the radical species. In some embodiments, the method further includes depositing the silicon nitride layer, including flowing one or more silicon precursors into the processing volume of the processing chamber, exposing the substrate to the one or more silicon precursors, providing one or more radical co-reactants comprising the radical species of a second gas, and exposing the substrate to the one or more radical co-reactants.

In another embodiment, a method for a radical based treatment of a silicon nitride layer includes positioning a substrate on a substrate support disposed in the processing volume of a processing chamber and treating a silicon nitride layer which has been deposited on the substrate. Treating the silicon nitride layer includes flowing one or more radical species of a first gas comprising NH₃, N₂, H₂, He, Ar, or combinations thereof and exposing the deposited silicon nitride layer to the radical species. Herein the silicon nitride layer was deposited using a method that included flowing one or more silicon precursors into the processing volume of the processing chamber, exposing the substrate to the one or more silicon precursors, flowing one or more radical co-reactants comprising the radical species of a second gas, and exposing the substrate to the one or more radical co-reactants.

In another embodiment, a method of forming a silicon nitride layer includes depositing a silicon nitride layer and the radical based treatment of the deposited silicon nitride layer. Depositing the silicon nitride layer includes flowing one or more silicon precursors into a processing volume of a first processing chamber, exposing the substrate to the one or more silicon precursors, flowing one or more radical co-reactants comprising the radical species of a first gas, and exposing the substrate to the one or more radical co-reactants. Treating the deposited silicon nitride layer includes flowing one or more radical species of a second gas comprising NH₃, N₂, H₂, He, Ar, or combinations thereof and exposing the deposited silicon nitride layer to the radical species of the second gas.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic cross sectional view of an example processing chamber which may be used to practice the methods described herein.

FIG. 2 is a flow diagram setting forth a method for the radical based treatment of a silicon nitride layer.

### DETAILED DESCRIPTION

Embodiments described herein generally relate to methods for radical based treatment of silicon nitride layers disposed on a substrate surface, in particular, to methods for radical based treatment of silicon nitride layers which have been deposited using a flowable chemical vapor deposition (FCVD) process. Flowable silicon nitride processes, e.g., silicon nitride layers deposited using a (FCVD) process, generally provide for improved gap fill performance of high aspect ratio features when compared to silicon nitride layers deposited using conventional methods. However, the silicon nitride layers typically provided by an FCVD process undesirably comprise a complex network of one or both of Si—H and Si—NH bonds and undesirably provide a lower silicon nitride layer film density when compared to conventionally deposited (non-flowable) silicon nitride layers. Conventional treatment methods to improve the film quality of a silicon nitride layer may include exposing a deposited silicon nitride layer to a high density plasma (HDP). Unfortunately, HDP treatment undesirably exposes layers and features underlying the treated layer to damage from the ion bombardment of the treated layer. Therefore, embodiments herein provide for treatment of FCVD deposited silicon nitride layers with gas radicals, which facilitate further crosslinking, densification, and nitrogen incorporation (nitridation) at desired treatment depths into the silicon nitride layer being treated. The methods provided herein desirably remove hydrogen impurities and increase the number of stable S—N bonds therein, without exposing the silicon nitride layer, or features and material layers disposed therebeneath, to the risk of damage thereto resulting from ion bombardment of the treated layer.

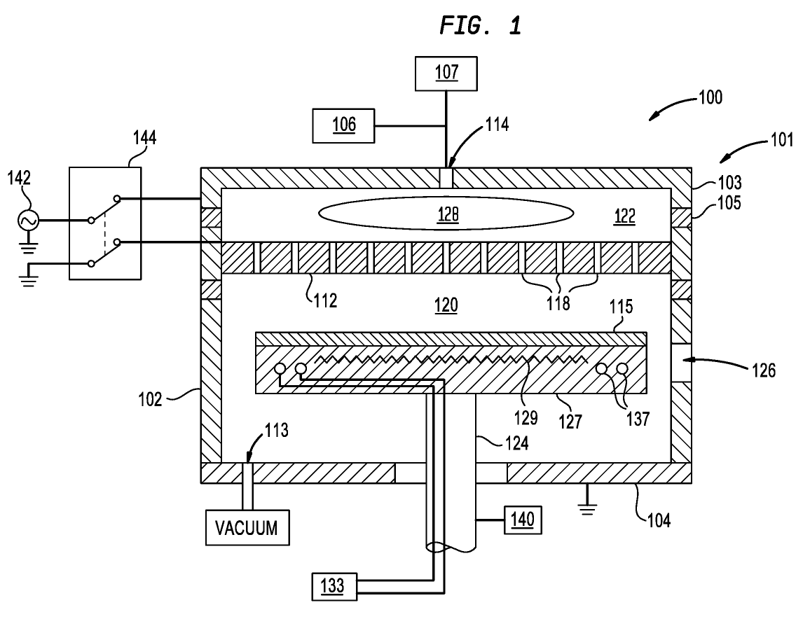

FIG. 1 is a schematic cross sectional view of an example processing chamber which may be used to practice the methods described herein. Here, the processing chamber 100 features a chamber lid assembly 101, one or more sidewalls 102, and a chamber base 104 which collectively define a processing volume 120. The chamber lid assembly 101 includes a chamber lid 103, a showerhead 112, and an electrically insulating ring 105, disposed between the chamber lid 103 and the showerhead 112, which define a plenum 122. A gas inlet 114, disposed through the chamber lid 103 is fluidly coupled to a gas source 106. In some embodiments, the gas inlet 114 is further fluidly coupled to a remote plasma source 107. The showerhead 112, having a plurality of openings 118 disposed therethrough, is used to uniformly distribute processing gases or gaseous radicals from the plenum 122 into the processing volume 120 through the plurality of openings 118.

In some embodiments, a power supply 142, such as an RF or VHF power supply, is electrically coupled to the chamber lid via a switch 144 when the switch is disposed in a first position (as shown). When the switch is disposed in a second position (not shown) the power supply 142 is electrically coupled to the showerhead 112. When the switch 144 is in the first position, the power supply 142 is used to ignite and maintain a first plasma which is remote from the substrate 115, such as the remote plasma 128 disposed in the plenum 122. The remote plasma 128 is composed of the processing gases flowed into the plenum and maintained as a plasma by the capacitive coupling of the power from the power supply 142 therewith. When the switch 144 is in the second position, the power supply 142 is used to ignite and maintain a second plasma (not shown) in the processing volume 120 between the showerhead 112 and the substrate 115 disposed on the substrate support 127.

The processing volume 120 is fluidly coupled to a vacuum source, such as to one or more dedicated vacuum pumps, through a vacuum outlet 113 which maintains the processing volume 120 at sub-atmospheric conditions and evacuates the processing and other gases therefrom. A substrate support 127, disposed in the processing volume 120, is disposed on a support shaft 124 sealingly extending through the chamber base 104, such as being surrounded by bellows (not shown) in the region below the chamber base 104. The support shaft 124 is coupled to a controller 140 that controls a motor to raise and lower the support shaft 124, and the substrate support 127 disposed thereon, to support a substrate 115 during processing thereof, and to transfer of the substrate 115 to and from the processing chamber 100.

The substrate 115 is loaded into the processing volume 120 through an opening 126 in one of the one or more sidewalls 102, which is conventionally sealed with a or door or a valve (not shown) during substrate 115 processing. Herein, the substrate 115 is transferred to and from the surface of the substrate support 127 using a conventional lift pin system (not shown) comprising a plurality of lift pins (not shown) movably disposed through the substrate support. Typically, the plurality of lift pins are contacted from below by a lift pin hoop (not shown) and moved to extend above the surface of the substrate support 127 lifting the substrate 115 therefrom and enabling access by a robot handler. When the lift pin hoop (not shown) is in a lowered position the tops of the plurality of lift pins are located to be flush with, or below, the surface of the substrate support 127 and the substrate rests thereon. The substrate support is moveable between a lower position, below the opening 126, for placement of a substrate thereon or removal of a substrate 115 therefrom, and a raised position for processing of the substrate 115. In some embodiments, the substrate support 127, and the substrate 115 disposed thereon, are maintained at a desired processing temperature using a resistive heating element 129 and/or one or more cooling channels 137 disposed in the substrate support. Typically, the cooling channels 137 are fluidly coupled to a coolant source 133 such as a modified water source having relatively high electrical resistance or a refrigerant source.

In some embodiments, the processing chamber 100 is further coupled to a remote plasma source 107 which provides gaseous radicals to the processing volume 120. Typically, the remote plasma source (RPS) comprises an inductively coupled plasma (ICP) source, a capacitively coupled plasma (CCP) source, or a microwave plasma source. In some embodiments, the remote plasma source is a standalone RPS unit. In other embodiments, the remote plasma source is a second processing chamber in fluid communication with the processing chamber 100. In other embodiments, the remote plasma source is the remote plasma 128 ignited and maintained in the plenum 122 between the chamber lid 103 and the showerhead 112. In some other embodiments, gaseous treatment radicals are provided to the processing chamber from a non-plasma based radical source, such as a UV source which uses UV radiation to photo-dissociate the first gas into the radical species thereof or a hot wire source, such as a hot wire CVD (HWCVD) chamber which uses thermal decomposition to dissociate the first gas into its radical species.

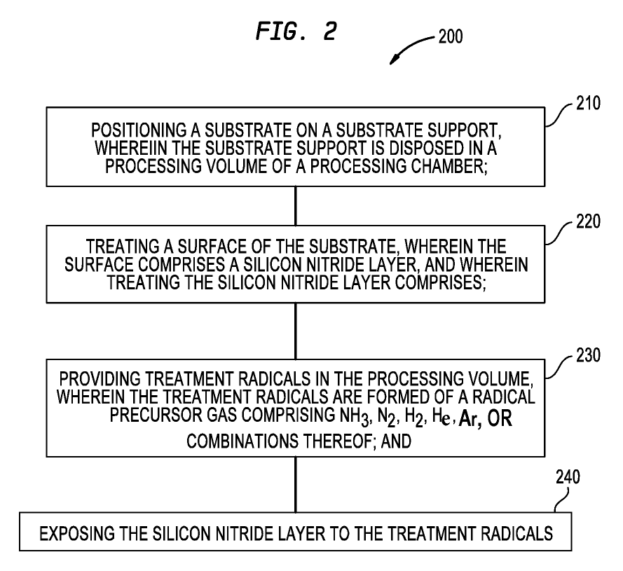

FIG. 2 is a flow diagram of a method to treating a silicon nitride layer using gaseous radicals. At activity 210 the method 200 includes positioning a substrate on a substrate support, the substrate support is disposed in a processing volume of a processing chamber, such as the processing chamber described in FIG. 1. Here, the substrate features a silicon nitride layer which has been deposited on a surface thereof.

In some embodiments, the silicon nitride layer is at least partially disposed in a plurality of openings formed in the surface of the substrate. In some of those embodiments, the plurality of openings have an aspect ratio (depth to width ratio) of more than 2:1, such as more than 5:1, more than 10:1, more than 20:1, for example more than 25:1. In some embodiments, the width of the openings is less than about 90 nm, such as less than about 65 nm, less than about 45 nm, less than about 32 nm, less than about 22 nm, for example less than about 16 nm, or between about 1 nm and about 90 nm, such as between about 16 nm and about 90 nm.

In some embodiments, the silicon nitride layer, e.g., a polysilazane layer, was deposited using a flowable chemical vapor deposition (FCVD) process. In some embodiments, the FCVD process is performed in the same processing chamber used for the radical based treatment of the silicon nitride layer. In some embodiments, the FCVD process is performed in a processing chamber which is different from the processing chamber used for the radical based treatment of the silicon nitride layer.

Typically, the FCVD process includes flowing one or more silicon precursors into the processing volume, exposing the substrate to the one or more silicon precursors, providing one or more radical co-reactants in the processing volume, and exposing the substrate to the one or more radical co-reactants. Here, exposing the substrate to the one or more silicon precursors and exposing the substrate to the one or more radical co-reactants is done sequentially, concurrently, or a combination thereof. For example, in some embodiments at least part of exposing the substrate to the one or more silicon precursors overlaps with at least part of exposing the substrate to the one or more radical co-reactants.

In some embodiments, the processing volume is purged between exposing the substrate to the one or more silicon precursors and exposing the substrate to the one or more radical co-reactants. Purging the processing volume includes flowing an inert gas into the processing volume to facilitate removal of some or all of the silicon precursor, the radicalized co-reactants, and processing gas byproducts therefrom. Typically, the pressure of the processing volume is desirably maintained at between about 10 mTorr and about 10 Torr, such as less than about 6 Torr, such as less than about 5 Torr, or between about 0.1 Torr and about 4 Torr, such as between about 0.5 Torr and about 3 Torr. In some embodiments, the substrate is desirably maintained at a temperature between about 0° C. and about 400° C., or less than about 200° C., such as less than about 150° C., less than about 100° C., for example less than about 75° C., or between about −10° C. and about 75° C., such as between about 20° C. and about 75° C.

In some embodiments, the one or more silicon precursors comprise a silane compound, such as silane (SiH₄), disilane (Si₂H₆), trisilane (Si₃H₈), and tetrasilane (Si₄H₁₀), or combinations thereof. In some other embodiments, the silicon precursor comprises a silazane compound having at least one Si—N—Si functional group, such as N,N′ disilyltrisilazane (A), other silazane compounds such as silazane compounds (A)-(E) below, for example trisilylamine (TSA) shown as (E) below, or combinations thereof. In some embodiments, the silicon precursor comprises a combination of one or more silane compounds and one or more silazane compounds. In some embodiments, the silicon precursor is substantially carbon-free, where substantially carbon-free means that the silicon precursor does not have a carbon moiety therein.

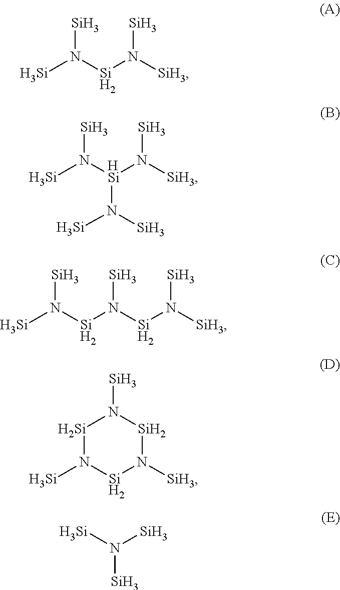

In some embodiments, the one or more radical co-reactants comprise the radical species of a second gas, such as a nitrogen containing second gas, for example NH₃, N₂, or combinations thereof. For example, in some embodiments the radical species of the second gas include NH₂, NH, N, and H radicals, or combinations thereof. In some embodiments, the second gas is substantially free of oxygen. Herein, the radical co-reactants are provided to the processing volume using a remote plasma source (RPS) or by a capacitively coupled plasma (CCP).

In some embodiments, the capacitively coupled plasma is formed of the second gas which is ignited and maintained in the processing volume between a showerhead and a chamber lid, such as the remote plasma 128 ignited and maintained in the plenum 122 described in FIG. 1. Typically, the FCVD process described above desirably provides a flowable silicon nitride film that enables the bottom up filling of high aspect ratio openings formed in the surface of the substrate. For example, the FCVD process may be used to fill openings having a width less than 90 nm and an aspect ratio of more than about 10:1. In some embodiments, the substrate is maintained at a temperature below about 200° C.

At activity 220 the method 200 includes providing gaseous treatment radicals to the processing volume of the processing chamber. Herein, the gaseous treatment radicals comprise plasma activated radical species of a first gas selected from the group consisting of NH₃, N₂, H₂, He, Ar, or combinations thereof. In some embodiments, the molecules of the first gas are activated to form the treatment radicals using a remote plasma source (RPS) fluidly coupled to the processing volume, such as the remote plasma source 107 described in FIG. 1. In other embodiments, the first gas is flowed into a plenum disposed between a showerhead and a chamber lid, such as the plenum 122 described in FIG. 1. In some of those embodiments, the treatment radicals are formed by igniting and maintaining a remote plasma, such as the remote plasma 128, of the first gas through capacitive coupling energy therewith.

At activity 230 the method 200 includes exposing the FCVD deposited silicon nitride layer to the gaseous treatment radicals to form a treated silicon nitride layer. In some embodiments, FCVD depositing the silicon nitride layer and exposing the FCVD deposited silicon nitride layer to the gaseous treatment radicals are done in the same processing chamber. In some of those embodiments, the processing volume of the processing chamber is purged after depositing the silicon nitride layer, and before exposing the silicon nitride layer to the gaseous treatment radicals, using an inert purge gas such as Ar, N₂, or combinations thereof. Purging the processing volume removes some or all of the unreacted silicon precursor, the unreacted radicalized co-reactants, and other processing gas byproducts from the processing volume. In other embodiments, exposing the FCVD deposited silicon nitride layer to the gaseous treatment radicals is done in a different processing chamber, herein a second processing chamber, than the processing chamber, e.g., a first processing chamber, used to deposit the silicon nitride layer. In some of those other embodiments, the second processing chamber used for the radical based treatment of the silicon nitride layer and a first processing chamber used for depositing the silicon nitride layer are coupled by a transfer chamber. Typically, the transfer chamber is continuously maintained under vacuum so that the substrate is not exposed to atmospheric conditions between the first processing chamber and the second processing chamber.

In some embodiments, the second processing chamber is an ultra violet radiation (UV) chamber. In those embodiments, the first gas used to form the treatment radicals is flowed into a processing volume of the processing chamber and exposed to UV radiation from a UV radiation source, where exposure of the radical precursor to UV radiation provides for photo-dissociation of the first gas into the desired treatment radicals thereof. Typically, the UV chamber is maintained at a pressure between about 10 mTorr and about 500 Torr and the substrate is maintained at between about 0° C. and about 400° C. In some embodiments, the second processing chamber comprises a plurality of heating elements, such as the heating filaments of a hot wire CVD (HWCVD) chamber. The heating elements are maintained at a temperature sufficient to thermally decompose the first gas into the desired treatment radicals thereof.

In some embodiments, the method 200 includes sequential repetitions of depositing at least part of the silicon nitride layer and then the radical based treatment of the at least partially deposited silicon nitride layer until a desired silicon nitride layer thickness is reached. Typically, the sequential repetitions facilitate more uniform densification and stoichiometry of the resulting treated silicon nitride layer when compared to depositing the silicon nitride layer to the desired thickness followed by the radical based treatment thereof.

Benefits of the methods described herein include improved densification and stoichiometry of the treated silicon nitride when compared to conventional treatment methods, such as exposing the nitride layer to a high density plasma. While not wishing to be bound by any particular theory it is believed that NH, radicals provided by the methods described herein react with the as deposited silicon nitride layer inserting N into a polymer matrix thereof, which improves the film stoichiometry, and further crosslink the polymeric film by removing H therefrom which leads to densification thereof.

While the foregoing is directed to embodiments of the present disclosure, other and further embodiments of the disclosure may be devised without departing from the basic scope thereof, and the scope thereof is determined by the claims that follow.

What is claimed is:

1. A method of processing a substrate, comprising:
positioning the substrate on a substrate support disposed in a processing volume of a processing chamber;
treating a silicon nitride layer which has been deposited on the substrate, comprising:
flowing one or more radical species of a first gas comprising NH₃, N₂, H₂, He, Ar, or combinations thereof; and
exposing the silicon nitride layer to the radical species.

2. The method of claim 1, wherein the one or more radical species of the first gas are flowed to the processing volume of the processing chamber from a remote plasma source in fluid communication therewith.

3. The method of claim 1, wherein, flowing the one or more radical species of the first gas comprises:
flowing the first gas into the processing volume of the processing chamber; and
forming a remote plasma of the first gas by capacitively coupling energy therewith.

4. The method of claim 1, further comprising depositing the silicon nitride layer on the substrate, comprising:
flowing one or more silicon precursors into the processing volume of the processing chamber;
exposing the substrate to the one or more silicon precursors;
flowing one or more radical co-reactants comprising the radical species of a second gas; and
exposing the substrate to the one or more radical co-reactants.

5. The method of claim 4, wherein flowing the one or more radical species of the second gas comprises:
flowing the second gas into the processing volume of the processing chamber; and
forming a remote plasma of the second gas by capacitively coupling energy therewith.

6. The method of claim 4, wherein depositing the silicon nitride layer comprises maintaining the substrate at a temperature less than about 200° C.

7. The method of claim 4, wherein a pressure of the processing volume of the processing chamber is maintained at about less than 6 Torr.

8. The method of claim 4, wherein the one or more silicon precursors are substantially carbon free.

9. The method of claim 4, wherein the one or more silicon precursors comprise a silazane compound.

10. The method of claim 4, wherein the one or more radical species of the second gas are flowed to the processing volume of the processing chamber from a remote plasma source in fluid communication therewith.

11. The method of claim 10, further comprising purging the processing volume using an inert purging gas flowed thereinto after depositing the silicon nitride layer and before treating the deposited silicon nitride layer.

12. A method for radical based treatment of a silicon nitride layer, comprising:
positioning a substrate on a substrate support disposed in a processing volume of a processing chamber; and
treating a silicon nitride layer which has been deposited on the substrate, comprising:
flowing one or more radical species of a first gas comprising NH₃, N₂, H₂, He, Ar, or combinations thereof; and
exposing the deposited silicon nitride layer to the radical species, wherein the silicon nitride layer was deposited using a method comprising:
flowing one or more silicon precursors into the processing volume of the processing chamber;
exposing the substrate to the one or more silicon precursors;
flowing one or more radical co-reactants comprising the radical species of a second gas; and
exposing the substrate to the one or more radical co-reactants.

13. The method of claim 12, wherein the one or more radical species of the first gas are flowed to the processing volume of the processing chamber from a remote plasma source in fluid communication therewith.

14. The method of claim 12, wherein the one or more radical species of the second gas are flowed to the processing volume of the processing chamber from a remote plasma source in fluid communication therewith.

15. The method of claim 12, wherein flowing the one or more radical species of the first gas comprises:
flowing the first gas into the processing volume of the processing chamber; and
forming a remote plasma of the first gas through capacitively coupling energy therewith.

16. A method of forming a silicon nitride layer, comprising:
depositing the silicon nitride layer on a substrate, comprising:
flowing one or more silicon precursors into a processing volume of a first processing chamber;
exposing the substrate to the one or more silicon precursors;
flowing one or more radical co-reactants comprising radical species of a first gas; and
exposing the substrate to the one or more radical co-reactants; and
treating the silicon nitride layer, comprising:
flowing one or more radical species of a second gas comprising NH₃, N₂, H₂, He, Ar, or combinations thereof; and
exposing the deposited silicon nitride layer to the radical species of the second gas.

17. The method of claim 16, further comprising transferring the substrate from the first processing chamber to a second processing chamber, wherein exposing the deposited silicon nitride layer to the radical species of the second gas is done in the second processing chamber.

18. The method of claim 16, wherein flowing the one or more radical species of the second gas comprises photo-dissociating the second gas into the one or more radical species using a UV-radiation source disposed in a second processing chamber.

19. The method of claim 16, wherein depositing the silicon nitride layer and treating the silicon nitride layer are done in the first processing chamber.

20. The method of claim 19, further comprising sequential repetitions of depositing the silicon nitride layer and then treating the silicon nitride layer.
